(19) United States
(12) Patent Application Publication
(10) Pub. No.: US 2025/0040308 A1
(43) Pub. Date: Jan. 30, 2025

(54) LIGHT EMITTING DIODE AND LIGHT EMITTING DEVICE

(71) Applicant: Tianjin Sanan Optoelectronics Co., Ltd., Tianjin (CN)

(72) Inventor: Taotao YIN, Tianjin (CN)

(73) Assignee: Tianjin Sanan Optoelectronics Co., Ltd., Tianjin (CN)

(21) Appl. No.: 18/776,172

(22) Filed: Jul. 17, 2024

(30) Foreign Application Priority Data
Jul. 25, 2023 (CN) 202310920395.6

(51) Int. Cl. H01L 33/44; H01L 33/40

(52) U.S. Cl. CPC H01L 33/44; H01L 33/405

(57) ABSTRACT

A light emitting diode includes a semiconductor stack layer, an insulative barrier layer, and a metal protective layer. The semiconductor stack layer includes a first semiconductor layer, a light emitting layer, and a second semiconductor layer. The insulative barrier layer is disposed on a lower surface of the semiconductor stack layer and has a first opening corresponding to a lower side of the first semiconductor layer. The metal protective layer is disposed on the lower surface of the semiconductor stack layer and connected to the insulative barrier layer. A portion of the metal protective layer is filled in the first opening. Vertical projection points of edge endpoints of an upper surface of the insulative barrier layer on a horizontal plane are distributed within a vertical projection first connecting line section of edge endpoints of an upper surface of the metal protective layer on the horizontal plane.

### CROSS-REFERENCE TO RELATED APPLICATION

This application claims the priority benefit of China application serial no. 202310920395.6, filed on Jul. 25, 2023. The entirety of the above-mentioned patent application is hereby incorporated by reference herein and made a part of this specification.

### BACKGROUND

### Technical Field

The disclosure relates to the field of semiconductor manufacturing technology, and in particular to a light emitting diode and a light emitting device.

### Description of Related Art

A light emitting diode (LED) is a semiconductor light emitting element, usually made of semiconductors such as GaN, GaAs, GaP, GaAsP, and the core thereof is a PN junction with light emitting properties. LED has the advantages of high luminous intensity, high efficiency, small size, and long service life, and is considered to be one of the most promising light sources currently. LED has been widely used in lighting, monitoring and command, high-definition broadcasting, high-end cinemas, office displays, conference interaction, virtual reality, and other fields.

In order to meet the market requirements, LED has developed ultra-high power and high-power horizontal structure dies. The high-power horizontal structure adopts the thermoelectric separation design, which has the characteristics of high current density, ultra-high brightness, and good aging performance. Packaging manufacturers usually adopt high-voltage series packaging, which can effectively expand the light-emitting area and meet product usage requirements.

The process flow of the high-power horizontal structure is more complicated than other series of LED chips, which requires two flipping processes and two mesa ICP etching processes to form a chip structure with the P-side facing up and the P electrode and N electrode on the same side. At present, in the high-power horizontal structure dies, the current blocking layer (CBL) usually adopts SiO₂ material, and except for the opening reserved for the N-side electrode electrical conduction, other positions are covered with the entire surface, so that the conductive structure is insulated and separated from the epitaxial layer to increase the uniformity of current flow and improve the luminous efficiency of the LED. However, the approach causes the following problems in the subsequent two flipping processes: since the current blocking layer covers the entire surface, during the stage of removing the temporary substrate, due to the HF immersion method is adopted, the current blocking layer of SiO₂ material is very easy to be etched away during the HF immersion process, which causes the structure to fall off, and the quality of the light-emitting diode is greatly affected.

It should be noted that the information disclosed in this background technology section is only intended to increase the understanding of the overall background of the disclosure, and should not be regarded as admitting or suggesting in any form that the information constitutes related art already known to persons skilled in the art.

### SUMMARY

The disclosure provides a light emitting diode, which includes a semiconductor stack layer, an insulative barrier layer, and a metal protective layer.

The semiconductor stack layer has a lower surface and an upper surface opposite to each other, and the semiconductor stack layer includes a first semiconductor layer, a light emitting layer, and a second semiconductor layer sequentially from the lower surface to the upper surface. The insulative barrier layer is disposed on the lower surface of the semiconductor stack layer. The insulative barrier layer has a first opening, and the first opening corresponds to a lower side of the first semiconductor layer. The metal protective layer is disposed on the lower surface of the semiconductor stack layer and connected to the insulative barrier layer, and a portion of the metal protective layer is filled in the first opening. Vertical projection points of edge endpoints of an upper surface of the insulative barrier layer on a horizontal plane are distributed within a vertical projection first connecting line section of edge endpoints of an upper surface of the metal protective layer on the horizontal plane.

The disclosure further provides a light emitting device, which adopts the light emitting diode provided by any one of the above embodiments.

In the light emitting diode and the light emitting device according to an embodiment of the disclosure, through the disposition of the vertical projection points being distributed within the vertical projection first connecting line section, the metal protective layer is connected to the outermost side of the insulative barrier layer, thereby the problem of the insulative barrier layer easily falling off during the fabrication process can be avoided, and the quality of the light-emitting diode is ensured.

Other features and beneficial effects of the disclosure will be described in the following description, and some of the technical features and beneficial effects may be easily derived from the description or understood by implementing the disclosure.

### BRIEF DESCRIPTION OF THE DRAWINGS

In order to more clearly illustrate the embodiments of the disclosure or the technical solutions in the related art, a brief introduction is given below to the drawings required for use in the embodiments or the description of the related art. Certainly, some of the drawings described below are some embodiments of the disclosure. For ordinary technicians in this field, other drawings may be obtained based on the drawings without creative effort.

FIG. 1 is a schematic structural diagram of a light emitting diode provided in an embodiment of the disclosure.

FIG. 2 is a schematic diagram of vertical projections of edge endpoints of an upper surface of an insulative barrier layer on a horizontal plane, a connecting line of edge endpoints of an upper surface of a metal protective layer on the horizontal plane, a lower surface of a light emitting layer on a horizontal plane, and a lower surface of a metal reflection structure on a horizontal plane corresponding to FIG. 1.

FIG. 3 is a schematic structural diagram of a top view of the light emitting diode provided in an embodiment of the disclosure.

FIG. 4 is a schematic structural diagram of a conventional light emitting diode.

FIG. 5 to FIG. 15 are schematic structural diagrams of the light emitting diode shown in FIG. 1 at various stages during a manufacturing process.

### DESCRIPTION OF THE EMBODIMENTS

In order to make the purpose, technical solution, and advantages of the embodiments of the disclosure clearer, the technical solution in the embodiments of the disclosure will be clearly and completely described below together with the drawings in the embodiments of the disclosure. Certainly, the embodiments are only part of the embodiments of the disclosure, not all of the embodiments; the technical features designed in different embodiments of the disclosure described below may be combined with each other as long as the features do not conflict with each other; based on the embodiments of the disclosure, all other embodiments obtained by ordinary technicians in this field without making any creative work shall fall within the scope of protection of the disclosure.

In the description of the disclosure, it should be understood that the terms, for example, “center”, “lateral”, “up”, “down”, “left”, “right”, “vertical”, “horizontal”, “top”, “bottom”, “inside”, “outside”, indicating the orientation or position relationship are based on the orientation or position relationship shown in the drawings, and are only for the convenience of describing the disclosure and simplifying the description, rather than indicating or implying that the device or component referred to has to have a specific orientation, or be constructed and operated in a specific orientation, and thus cannot be understood as a limitation on the disclosure. In addition, the terms “first” and “second” are used for descriptive purposes only and should not be understood as indicating or implying relative importance or implicitly indicating the quantity of the indicated technical features. Therefore, features defined as “first” or “second” may explicitly or implicitly include one or more of such features. In the description of the disclosure, unless otherwise specified, “plurality” means two or more. In addition, the term “include” and any variations thereof all mean “include at least”.

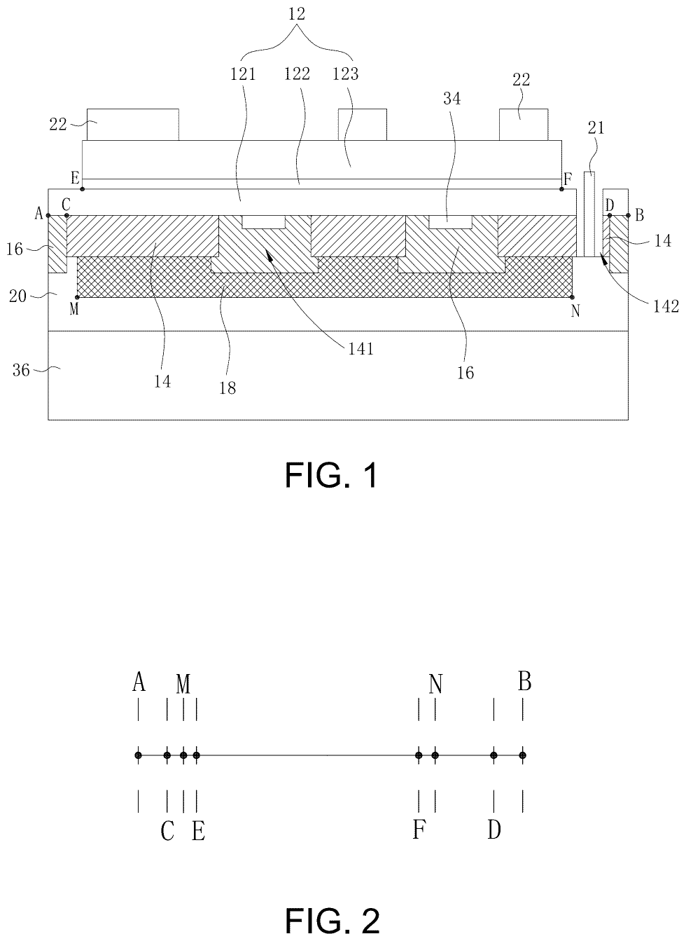

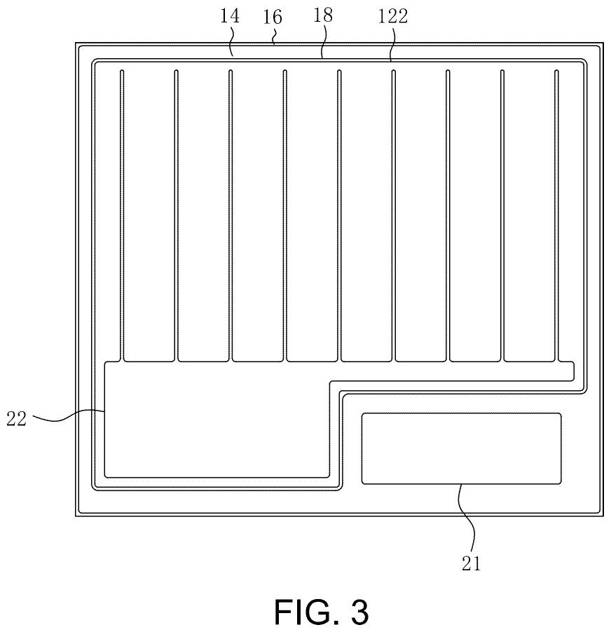

Please refer to FIG. 1, FIG. 2, and FIG. 3. FIG. 1 is a schematic structural diagram of a light emitting diode provided in an embodiment of the disclosure, FIG. 2 is a schematic diagram of vertical projections of edge endpoints of an upper surface of an insulative barrier layer 14 on a horizontal plane, a connecting line of edge endpoints of an upper surface of a metal protective layer 16 on the horizontal plane, a lower surface of a light emitting layer 122 on a horizontal plane, and a lower surface of a metal reflection structure 18 on a horizontal plane corresponding to FIG. 1, and FIG. 3 is a schematic structural diagram of a top view of the light emitting diode provided in an embodiment of the disclosure. It should be noted that in FIG. 2, in order to make the points in the drawing clearer, the length of the line section from a point E to a point F is shortened. To achieve at least one of the above advantages or other advantages, a light emitting diode is provided by an embodiment of the disclosure. As shown in the drawing, the light emitting diode includes a semiconductor stack layer 12, the insulative barrier layer 14, and the metal protective layer 16.

The semiconductor stack layer 12 has a lower surface and an upper surface opposite to each other, and the semiconductor stack layer 12 includes a first semiconductor layer 121, the light emitting layer 122, and a second semiconductor layer 123 sequentially from the lower surface to the upper surface. That is, the light emitting layer 122 is located between the first semiconductor layer 121 and the second semiconductor layer 123.

The first semiconductor layer 121 may be an N-type semiconductor layer, and may provide electrons to the light emitting layer 122 under the action of a power source. The first semiconductor layer 121 may be implemented as a material layer providing electrons by n-type doping. The N-type semiconductor layer may be doped with an n-type dopant such as Si, Ge, or Sn.

The light emitting layer 122 may be a quantum well (QW) structure. In some embodiments, the light emitting layer 122 may also be a multiple quantum well (MQW) structure, in which the multiple quantum well structure includes multiple quantum well layers and multiple quantum barrier layers alternately arranged in a repeated manner, and may be, for example, a multiple quantum well structure of GaN/AlGaN, InAlGaN/InAlGaN, or InGaN/AlGaN. In addition, the composition and thickness of the well layer in the light emitting layer 122 determine the wavelength of the generated light. In order to improve the luminous efficiency of the light emitting layer 122, the depth of the quantum well, the number of layers and the thicknesses of the paired quantum wells and quantum barriers, and/or other characteristics in the light emitting layer 122 may be changed.

The second semiconductor layer 123 may be a P-type semiconductor layer, and may provide holes to the light emitting layer 122 under the action of a power source. The second semiconductor layer 123 may be implemented as a material layer providing holes by p-type doping. The p-type semiconductor layer may be doped with a p-type dopant such as Mg, Zn, Ca, Sr, or Ba. The second semiconductor layer 123 may have a single-layer structure or a multi-layer structure, and the multi-layer structure has different compositions.

The first semiconductor layer 121, the light emitting layer 122, and the second semiconductor layer 123 may be specifically made of materials such as aluminum gallium indium nitride, gallium nitride, aluminum gallium nitride, aluminum indium phosphide, aluminum gallium indium phosphide, gallium arsenide, or aluminum gallium arsenide. The first semiconductor layer 121 or the second semiconductor layer 123 includes a cover layer providing electrons or holes and may include other layer materials, such as a current expansion layer, a window layer, or an ohmic contact layer, which are arranged as different layers according to different doping concentrations or component contents. The light emitting layer 122 is a region providing light radiation for recombination of electrons and holes, and different materials may be selected according to different luminous wavelengths. The light emitting layer 122 may be a single quantum well or a periodic structure of multiple quantum wells. By adjusting the composition ratio of the semiconductor materials in the light emitting layer 122, it is desired to radiate light of different wavelengths. In this embodiment, the material of the light emitting layer 122 is preferably aluminum gallium indium phosphide or aluminum gallium arsenic material. The light emitting layer 122 may radiate red light or infrared light. That is, the semiconductor stack layer 12 may radiate infrared light, and the light emitting diode may be an infrared light emitting diode.

The insulative barrier layer 14 is disposed on the lower surface of the semiconductor stack layer 12 to insulate and separate the conductive structure from the semiconductor stack layer 12, thereby the uniformity of current flow is increased, and the luminous efficiency of the light emitting diode is improved. The insulative barrier layer 14 has a first opening 141. The first opening 141 corresponds to a lower side of the first semiconductor layer 121, so that an electrode may be electrically connected to the first semiconductor layer 121 through the first opening 141 to form a good ohmic contact. The insulative barrier layer 14 is prepared and formed by adopting insulating materials, such as SiO₂ material.

The metal protective layer 16 is disposed on the lower surface of the semiconductor stack layer 12 and is connected to the insulative barrier layer 14. A portion of the metal protective layer 16 is filled in the first opening 141 of the insulative barrier layer 14 to form a good ohmic contact with the first semiconductor layer 121. The metal protective layer 16 may be prepared and formed by a metal material. The material of the metal protective layer 16 is at least one selected from a group comprising Au, Ge, and Ni. For example, the metal protective layer 16 is an alloy metal structure of AuGeNi. Optionally, the upper surface of the metal protective layer 16 and the upper surface of the insulative barrier layer 14 are located on the same horizontal plane to ensure the flatness of the surface of the structure.

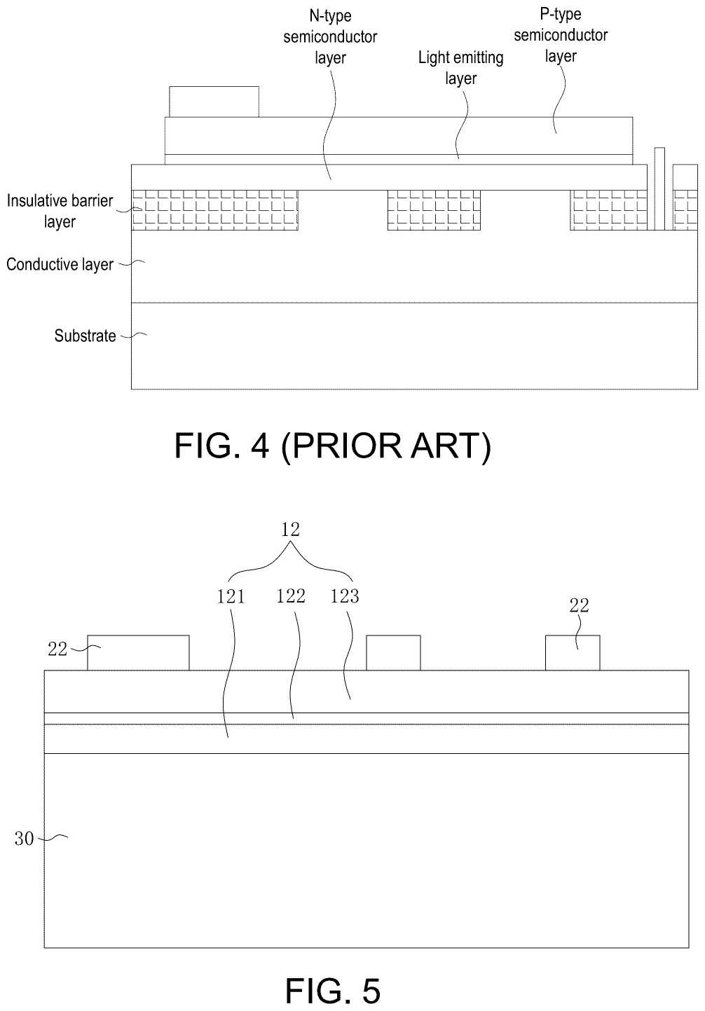

Vertical projection points of edge endpoints of the upper surface of the insulative barrier layer 14 on the horizontal plane are distributed within the vertical projection first connecting line section of edge endpoints of the upper surface of the metal protective layer 16 on the horizontal plane. Specifically, as shown in FIG. 1 and FIG. 2, the vertical projection points of the edge endpoints of the upper surface of the insulative barrier layer 14 on the horizontal plane are points C, D. The vertical projection points of the edge endpoints of the upper surface of the metal protective layer 16 on the horizontal plane are points A, B. The line section connecting the points A, B is the vertical projection first connecting line section, the points C, D both fall within the vertical projection first connection line section, so that the metal protective layer 16 is connected to the outermost side of the insulative barrier layer 14, thereby the problem of the insulative barrier layer 14 easily falling off during the fabrication process can be avoided, and the quality of the light-emitting diode is ensured. In contrast, in the conventional light emitting diode shown in FIG. 4, the outermost side of the insulative barrier layer 14 is exposed, during the fabrication stage of removing a temporary carrier substrate 36, due to the HF immersion method is adopted, the exposed insulative barrier layer 14 of SiO₂ material is etched away during the HF immersion process, which causes the structure to fall off, and the quality of the light-emitting diode is greatly affected.

Optionally, the minimum spacing from the vertical projection points to the endpoints of

the vertical projection first connecting line section is in a range of 3 μm to 7 μm. That is, the distance from the point C to the point A is in a range of 3 μm to 7 μm, and the distance from the point D to the point B is in a range of 3 μm to 7 μm. If the range of the distance is too large (for example, greater than 7 μm), which leads to too much retraction of the insulative barrier layer 14, then the blocking effect of the insulative barrier layer 14 is deteriorated, thereby the light outputting brightness of the light emitting diode is affected; if the range of the distance is too small (for example, less than 3 μm), then the width of the metal protective layer 16 is too narrow, which reduces the protective effect against solution erosion and results in poor barrier effect, thereby the risk of the structure falling off still exists.

In some embodiments, a first vertical projection line section of the lower surface of the light emitting layer 122 on a horizontal plane is located within the vertical projection first connecting line section, and the vertical projection points are located outside the first vertical projection line section. Specifically, as shown in FIG. 1 and FIG. 2, the first vertical projection line section of the lower surface of the light emitting layer 122 on the horizontal plane refers to the line section connecting a point E and a point F. That is, the EF line section falls within the AB line section, while the points C, D are located outside the EF line section, so that the insulative barrier layer 14 can play a more effective current blocking effect. If the points C, D fall within the EF line section, then the current blocking effect of the insulative barrier layer 14 is deteriorated, thereby the optical performance of the light emitting diode is reduced. Furthermore, if the insulative barrier layer 14 is to be shrunk within the semiconductor stack layer 12 (that is, the points C, D are located within the line section EF), an additional step needs to be set up in the process to remove the redundant semiconductor stack layer 12, which makes the process more complicated and not conducive to production and fabrication.

The light emitting diode may further include the metal reflection structure 18, a conductive layer 20, a first electrode 21, and a second electrode 22.

The metal reflection structure 18 is disposed on the lower surface of the insulative barrier layer 14 and is connected to the metal protective layer 16 located in the first opening 141. In addition to the electrical conduction function thereof, the metal reflection structure 18 may also be used to reflect light to enhance the light output of the light emitting diode. The metal reflection structure 18 may be a single-layer, double-layer, or multi-layer structure. The material of the metal reflection structure 18 may be at least one selected from a group comprising a transparent conductive material, Au, Ag, Pt, and Ti. The transparent conductive material may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but the embodiments of the disclosure are not limited thereto.

A first vertical projection line section of the lower surface of the light emitting layer 122 on the horizontal plane is located within a second vertical projection line section of the lower surface of the metal reflection structure 18 on the horizontal plane, the second vertical projection line section is located within the vertical projection first connecting line section, and the vertical projection points are located outside the second vertical projection line section. Specifically, as shown in FIG. 1 and FIG. 2, the first vertical projection line section of the lower surface of the light emitting layer 122 on the horizontal plane refers to the line section connecting the point E and the point F, and the second vertical projection line section of the lower surface of the metal reflection structure 18 on the horizontal plane refers to the line section connecting a point M and a point N. That is to say, the EF line section falls within the MN line section, the MN line section falls within the AB line section, and the points C, D are outside the MN line section. If the EF line section is outside the MN line section, then the reflection effect of the metal reflection structure 18 on the upper light emitting layer 122 is deteriorated. If the point C and the point D are located within the MN line section, then gaps are formed between the left and right ends of the metal reflection structure 18 in the region corresponding to the upper first semiconductor layer 121, thereby affecting the optical effect and reliability of the light emitting diode. Optionally, the minimum spacing from the vertical projection points to the endpoints of the second vertical projection line section is greater than or equal to 1 μm, that is, the spacing from the point C to the point M is ≥1 μm, and the spacing from the point D to the point N is ≥1 μm, so as to avoid affecting the optical effect and reliability of the light emitting diode.

The conductive layer 20 covers the metal reflection structure 18 to provide a conducting function. The conductive layer 20 may be a single-layer, double-layer, or multi-layer structure, and the material of the conductive layer 20 may be at least one selected from a group comprising Ti, Pt, and Au. For example, the conductive layer 20 is a multi-layer stacked metal structure of Ti/Pt/Au. The insulative barrier layer 14 further has a second opening 142, and the second opening 142 is used to expose the conductive layer 20 located below the insulative barrier layer 14, so as to facilitate the subsequent disposition of a metal pad at the second opening 142.

The first electrode 21 is connected to the conductive layer 20 through the second opening 142. The first electrode 21 and the semiconductor stack layer 12 are spaced apart to avoid a short circuit problem. The second electrode 22 is connected to the second semiconductor layer 123. The second electrode 22 may include an extended electrode to facilitate current expansion and improve the optical performance of the light emitting diode.

A fabrication method of the light-emitting diode shown in FIG. 1 is disclosed below. Please refer to FIG. 5 to FIG. 15. FIG. 5 to FIG. 15 are schematic structural diagrams of the light-emitting diode shown in FIG. 1 at various stages during the manufacturing process.

First, as shown in FIG. 5, a first semiconductor layer 121, a light emitting layer 122, and a second semiconductor layer 123 are sequentially grown on a growth substrate 30 to form the semiconductor stack layer 12. The growth substrate 30 may be a GaAs carrier substrate, and then the second electrode 22 is formed on the upper surface of the second semiconductor layer 123.

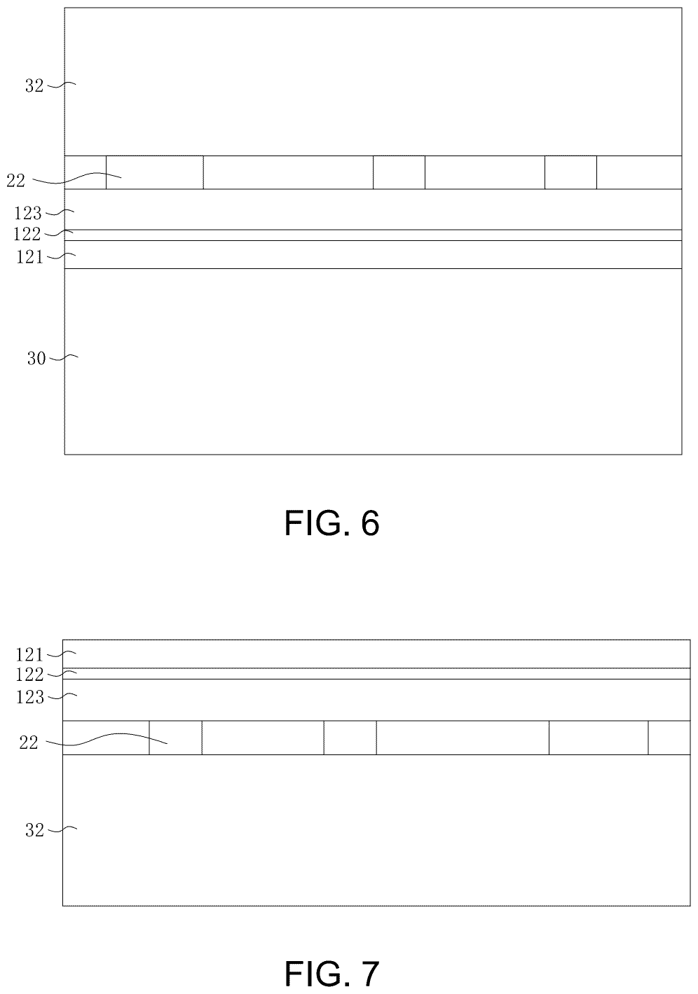

Next, as shown in FIG. 6, a glass substrate 32 is disposed on the second electrode 22 for a first flipping.

Next, as shown in FIG. 7, the entire structure is flipped over for a first time, the upper and lower position relationship of the first semiconductor layer 121 and the second semiconductor layer 123 is reversed, and then the growth substrate 30 located on the first semiconductor layer 121 is removed.

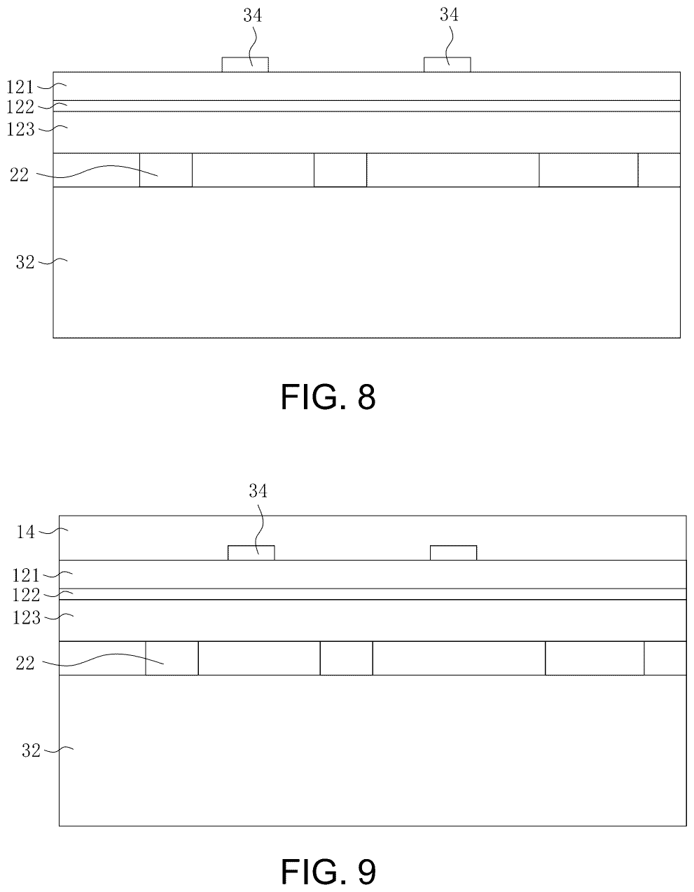

Then, as shown in FIG. 8, a surface layer structure 34 is disposed on the surface of the first semiconductor layer 121 for subsequent formation of an ohmic contact. The surface layer structure 34 may adopt a GaAs layer doped with N-type impurities. The surface layer structure 34 is not required to be disposed. The purpose of disposing the surface layer structure 34 is to form a good ohmic contact. In some embodiments, the process of disposing the surface layer structure 34 may be omitted and the next process may be directly performed.

Then, as shown in FIG. 9, the insulative barrier layer 14 covers the entire surface on the first semiconductor layer 121 and the surface layer structure 34. When the surface layer structure 34 is not disposed, the insulative barrier layer 14 covers the entire surface on the first semiconductor layer 121.

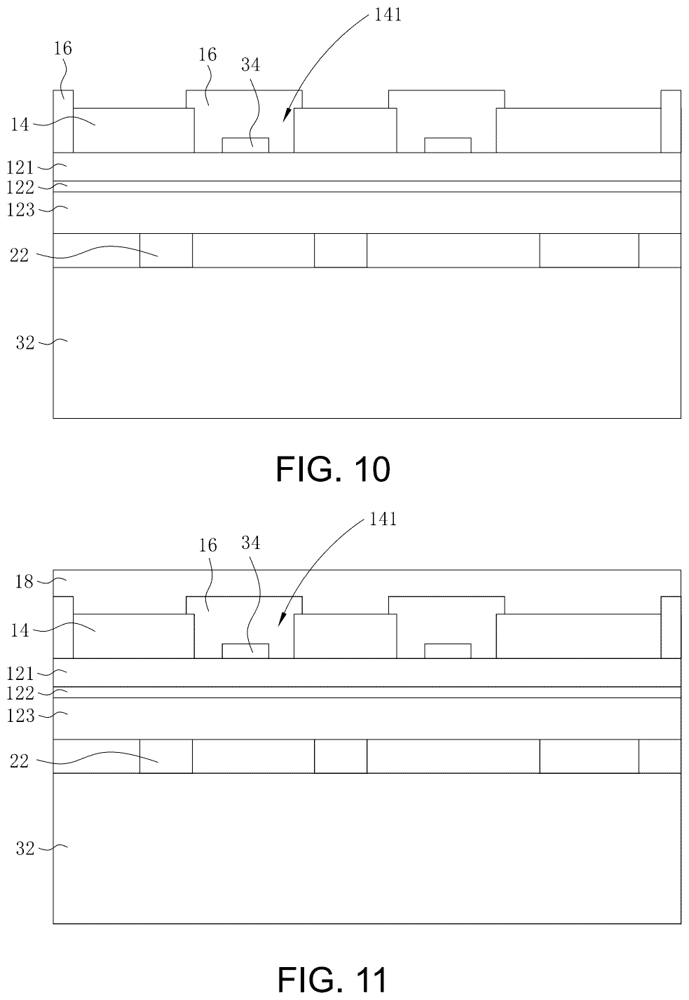

Then, as shown in FIG. 10, the insulative barrier layer 14 covering the surface layer structure 34 is etched away to form the first opening 141, so that an electrode is electrically connected to the first semiconductor layer 121 and the surface layer structure 34 through the first opening 141 to form a good ohmic contact. At the same time, the insulating barrier layer 14 on peripheries of the left and right sides is etched away. Afterward, the metal protective layer 16 is disposed at the first opening 141 and at the insulative barrier layer 14 etched away on the left and right sides. When the surface layer structure 34 is not disposed, a portion of the insulative barrier layer 14 is etched away at a reserved position to form a first opening, so that an electrode is electrically connected to the first semiconductor layer 121 through the first opening 141.

Then, as shown in FIG. 11, the metal reflection structure 18 covers the entire surface on the metal protective layer 16 and the insulative barrier layer 14.

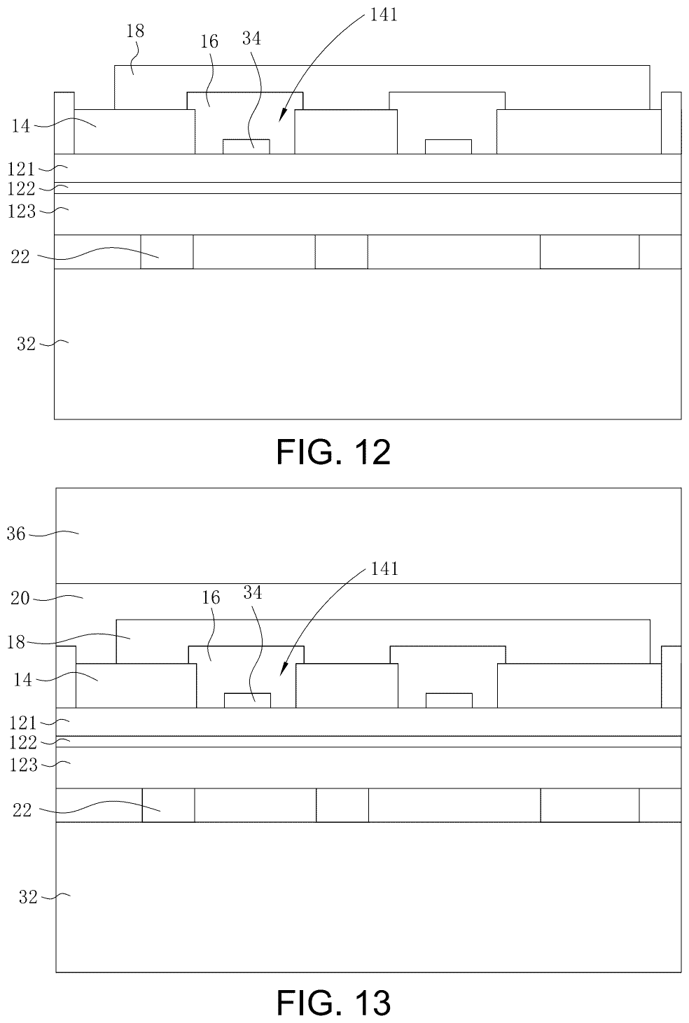

Then, as shown in FIG. 12, a portion of the metal reflection structure 18 is removed to expose a portion of the insulative barrier layer 14 and the metal protective layer 16.

Then, as shown in FIG. 13, the conductive layer 20 covers the entire surface on the metal reflection structure 18 and the insulative barrier layer 14. Next, the carrier substrate 36 is disposed on the conductive layer 20, and the carrier substrate 36 may be an AlN carrier substrate, in preparation for a second flipping.

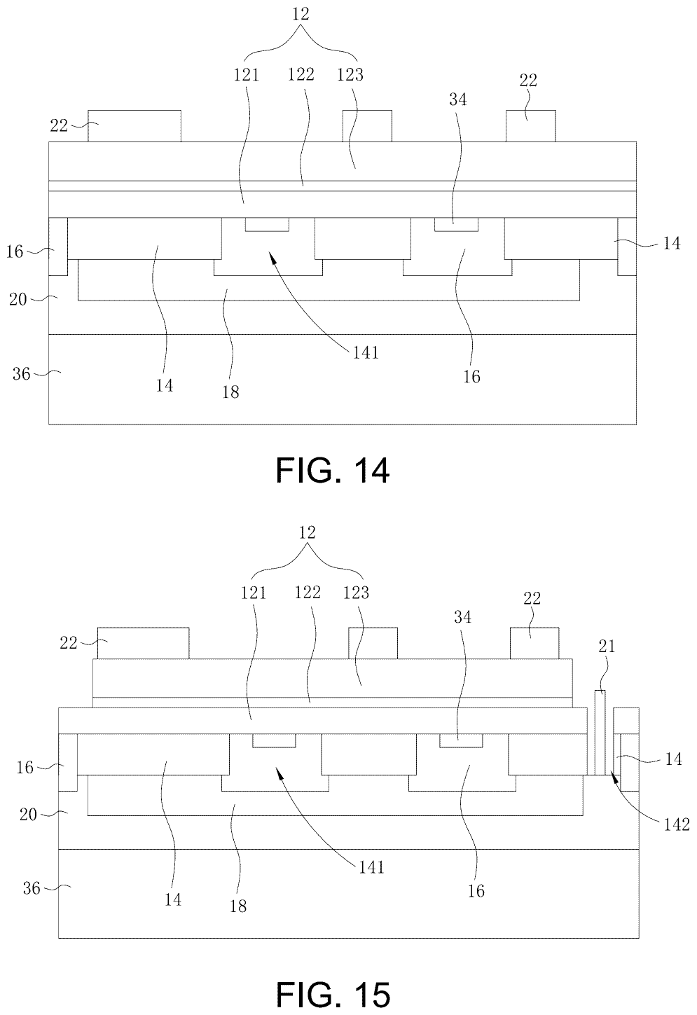

Then, as shown in FIG. 14, the entire structure is flipped over for a second time, so that the position relationship of the second semiconductor layer 123 being upper and the first semiconductor layer 121 being lower is formed again. Next, the glass substrate 32 is removed. During the stage of removing the glass substrate 32, the HF immersion method is adopted. At this time, the insulative barrier layer 14 is protected by the metal protective layer 16 and is not etched away during the HF immersion process, which avoids the risk of the structure falling off, and the quality of the light-emitting diode is ensured. Then, etching is performed downward from the upper surface of the second semiconductor layer 123 until the first semiconductor layer 121 is exposed to form a mesa, and the mesa is for subsequent electrode disposition.

Finally, as shown in FIG. 15, etching is performed downward from the upper surface of the exposed first semiconductor layer 121, and the underlying insulative barrier layer 14 is removed together, thereby the second opening 142 is formed, and the conductive layer 20 is exposed. Then, the first electrode 21 is disposed at the second opening 142, that is, the first electrode 21 is connected to the conductive layer 20 through the second opening 142.

The above is only a disclosed method for manufacturing the light-emitting diode shown in FIG. 1, the disclosure is not limited thereto, and the embodiment is only used to illustrate a fabrication implementation method of the light-emitting diode.

An embodiment of the disclosure further provides a light emitting device, which may adopt the light emitting diode of any of the above embodiments.

In the light emitting diode and the light emitting device according to an embodiment of the disclosure, through the disposition of the vertical projection points being distributed within the vertical projection first connecting line section, the metal protective layer 16 is connected to the outermost side of the insulative barrier layer 14, thereby the problem of the insulative barrier layer 14 easily falling off during the fabrication process can be avoided, and the quality of the light-emitting diode is ensured.

In addition, persons skilled in the art should understand that, although there are many problems in the related art, each embodiment or technical solution of the disclosure may perform improvement in only one or several aspects without having to solve all technical problems listed in the related art or background technology at the same time. It should be understood by persons skilled in the art that any content not mentioned in a claim should not be regarded as a limitation of the claim.

Finally, it should be noted that the above embodiments are only used to illustrate the technical solutions of the disclosure, rather than to limit the disclosure. Although the disclosure has been described in detail with reference to the embodiments, persons skilled in the art should understand that the technical solutions described in the embodiments may still be modified, or some or all of the technical features thereof may be substituted by equivalents. However, the modifications or substitutions do not make the essence of the corresponding technical solutions deviate from the scope of the technical solutions of the embodiments of the disclosure.

What is claimed is:

1. A light emitting diode, comprising:
a semiconductor stack layer having a lower surface and an upper surface opposite to each other, wherein the semiconductor stack layer comprises a first semiconductor layer, a light emitting layer, and a second semiconductor layer sequentially from the lower surface to the upper surface;
an insulative barrier layer disposed on the lower surface of the semiconductor stack layer, wherein the insulative barrier layer has a first opening, and the first opening corresponds to a lower side of the first semiconductor layer; and
a metal protective layer disposed on the lower surface of the semiconductor stack layer and connected to the insulative barrier layer, wherein a portion of the metal protective layer is filled in the first opening,
wherein vertical projection points of edge endpoints of an upper surface of the insulative barrier layer on a horizontal plane are distributed within a vertical projection first connecting line section of edge endpoints of an upper surface of the metal protective layer on the horizontal plane.

2. The light emitting diode according to claim 1, wherein a first vertical projection line section of a lower surface of the light emitting layer on a horizontal plane is located within the vertical projection first connecting line section, and the vertical projection points are located outside the first vertical projection line section.

3. The light emitting diode according to claim 1, further comprising a metal reflection structure, wherein the metal reflection structure is disposed on a lower surface of the insulative barrier layer and connected to the metal protective layer in the first opening.

4. The light emitting diode according to claim 3, wherein a first vertical projection line section of a lower surface of the light emitting layer on a horizontal plane is located within a second vertical projection line section of a lower surface of the metal reflection structure on a horizontal plane, the second vertical projection line section is located within the vertical projection first connecting line section, and the vertical projection points are located outside the second vertical projection line section.

5. The light emitting diode according to claim 4, wherein a minimum spacing from the vertical projection points to endpoints of the second vertical projection line section is greater than or equal to 1 μm.

6. The light emitting diode according to claim 3, further comprising a conductive layer, a first electrode, and a second electrode, wherein the conductive layer covers the metal reflection structure, the insulative barrier layer further has a second opening, the second opening exposes the conductive layer, the first electrode is connected to the conductive layer through the second opening, and the second electrode is connected to the second semiconductor layer.

7. The light emitting diode according to claim 3, wherein a material of the metal reflection structure is at least one selected from a group comprising a transparent conductive material, Au, Ag, Pt, and Ti.

8. The light emitting diode according to claim 6, wherein a material of the conductive layer is at least one selected from a group comprising Ti, Pt, and Au.

9. The light emitting diode according to claim 6, wherein the first electrode and the semiconductor stack layer are spaced apart.

10. The light emitting diode according to claim 1, wherein a minimum spacing from the vertical projection points to endpoints of the vertical projection first connecting line section is in a range of 3 μm to 7 μm.

11. The light emitting diode according to claim 1, wherein the upper surface of the metal protective layer and the upper surface of the insulative barrier layer located on the same horizontal plane.

12. The light emitting diode according to claim 1, wherein a material of the metal protective layer is at least one selected from a group comprising Au, Ge, and Ni.

13. The light emitting diode according to claim 1, wherein the semiconductor stack layer radiates infrared light.

14. A light emitting device, adopting the light emitting diode according to claim 1.
